(19) United States
(12) Patent Application Publication
(10) Pub. No.: US 2011/0157118 A1
(43) Pub. Date: Jun. 30, 2011

(54) DRIVE CIRCUIT AND DISPLAY DEVICE

(75) Inventors: Keisuke Omoto, Kanagawa (JP); Masatsugu Tomida, Kanagawa (JP)

(73) Assignee: Sony Corporation, Tokyo (JP)

(21) Appl. No.: 12/972,731

(22) Filed: Dec. 20, 2010

(30) Foreign Application Priority Data
Dec. 25, 2009 (JP) 2009-295551

(51) Int. Cl. G09G 5/00; H03K 3/00

(52) U.S. Cl. 345/208; 327/108

(57) ABSTRACT

A drive circuit includes an input-side inverter circuit and an output-side inverter circuit connected to each other in series and inserted between a high voltage line and a low voltage line. The output-side inverter circuit includes a first transistor of a dual-gate first electro-conductive type having a drain connected to the high voltage line side and a source connected to an output side of the output-side inverter circuit. The output-side inverter circuit further includes a second transistor of a dual-gate second electro-conductive type having a drain connected to the high voltage line side and a source connected to the output side of the output-side inverter circuit. The output-side inverter circuit further includes a third transistor having a drain connected to the low voltage line side and a source connected to the output side of the output-side inverter circuit.

### BACKGROUND OF THE INVENTION

1. Field of the Invention

The present invention relates to a drive circuit suitably applicable to a display device that uses, for example, an organic Electro Luminescence (EL) element. The present invention also relates to a display device having the drive circuit.

2. Description of the Related Art

In recent years, in the field of display devices displaying images, a display device that uses, as a light emitting element of a pixel, an optical element of current-driven type whose light emission intensity changes according to the value of a flowing current, e.g. an organic EL element, has been developed, and its commercialization is proceeding. In contrast to a liquid crystal device and the like, the organic EL element is a self-light-emitting element. Therefore, in the display device using the organic EL element (organic EL display device), gradation of coloring is achieved by controlling the value of a current flowing in the organic EL element.

As a drive system in the organic EL display device, like a liquid crystal display, there are a simple (passive) matrix system and an active matrix system. The former is simple in structure, but has, for example, such a problem that it is difficult to realize a large and high-resolution display device. Therefore, currently, development of the active matrix system is brisk. In this system, the current flowing in a light emitting element arranged for each pixel is controlled by a drive transistor.

In the above-mentioned drive transistor, there is a case in which a threshold voltage Vₜₕ or a mobility μ changes over time, or varies from pixel to pixel due to variations in production process. When the threshold voltage Vₜₕ or the mobility μ varies from pixel to pixel, the value of the current flowing in the drive transistor varies from pixel to pixel and therefore, even when the same voltage is applied to a gate of the drive transistor, the light emission intensity of the organic EL element varies and uniformity of a screen is impaired. Thus, there has been developed a display device in which a correction function to address a change in the threshold voltage Vₜₕ or the mobility μ is incorporated (see, for example, Japanese Unexamined Patent Application Publication No. 2008-083272).

A correction to address the change in the threshold voltage Vₜₕ or the mobility μ is performed by a pixel circuit provided for each pixel. As illustrated in, for example, FIG. 7, this pixel circuit includes: a drive transistor Tr₁ controlling a current flowing in an organic EL element 111, a write transistor Tr₂ writing a voltage of a signal line DTL into the drive transistor Tr₁, and a holding capacitance Cₛ, and therefore, the pixel circuit has a 2Tr1C circuit configuration. The drive transistor Tr₁ and the write transistor Tr₂ are each formed by, for example, an n-channel MOS Thin Film Transistor (TFT).

FIG. 6 illustrates an example of the waveform of a voltage applied to the pixel circuit and an example of a change in each of a gate voltage and a source voltage of the drive transistor. In Part (A) of FIG. 6, there is illustrated a state in which a signal voltage V_{sig} and an offset voltage \T_{ofs}, are applied to the signal line DTL. In Part (B) of FIG. 6, there is illustrated a state in which a voltage V_{dd} for turning on the drive transistor and a voltage Vₛₛ for turning off the drive transistor are applied to a write line WSL. In Part (C) of FIG. 6, there is illustrated a state in which a high voltage V_{ccH} and a low voltage V_{ccL} are applied to a power-source line PSL. Further, in Part (D) and (E) of FIG. 6, there is illustrated a state in which a gate voltage V_{g} and a source voltage Vₛ of the drive transistor Tr₁ change over time in response to the application of the voltages to the power-source line PSL, the signal line DTL and the write line WSL.

From FIG. 6, it is found that a WS pulse P1 is applied to the write line WSL twice within 1 H, a threshold correction is performed by the first WS pulse P1, and a mobility correction and signal writing are performed by the second WS pulse P1. In other words, in FIG. 6, the WS pulse P1 is used for not only the signal writing but also the threshold correction and the mobility correction of the drive transistor Tr₁.

In the following, the threshold correction and the mobility correction of the drive transistor Tr₁ will be described. By the application of the second WS pulse P1, the signal voltage V_{sig} is written into a gate of the drive transistor Tr₁. As a result, the drive transistor Tr₁ is turned on and a current flows in the drive transistor Tr₁. At the time, when a reverse bias is applied to the organic EL element 111, electric charge flowing out from the drive transistor Tr₁ fills the holding capacitance Cₛ and an element capacitance (not illustrated) of the organic EL element 111, causing a rise in the source voltage Vₛ. When the mobility of the drive transistor Tr₁ is high, the current flowing in the drive transistor Tr₁ is large and thus, the source voltage Vₛ rises quickly. On the contrary, when the mobility of the drive transistor Tr₁ is low, the current flowing in the drive transistor Tr₁ is small and thus, the source voltage Vₛ rises more slowly than when the mobility of the drive transistor Tr₁ is high. Therefore, it may be possible to correct the mobility by adjusting a period of time for correcting the mobility.

### SUMMARY OF THE INVENTION

Incidentally, in the display device employing the active matrix system, each of a horizontal drive circuit driving a signal line and a write scan circuit selecting each pixel sequentially is configured to basically include a shift resister (not illustrated), and has a buffer circuit for each stage, corresponding to each column or each row of pixels. For example, the buffer circuit in the scan circuit is typically configured such that, as illustrated in FIG. 8, two inverter circuits 210 and 220 are connected to each other in series. In a buffer circuit 200 in FIG. 8, the inverter circuit 210 has such a circuit configuration that a p-channel MOS transistor and an n-channel MOS transistor are connected to each other in parallel. On the other hand, the inverter circuit 220 has such a circuit configuration that a CMOS transistor and an n-channel MOS transistor are connected to each other in parallel. The buffer circuit 200 is inserted between high voltage line L_{H} to which a high-level voltage is applied and low voltage line L_{L} to which a low-level voltage is applied.

However, in the CMOS transistor of the buffer circuit 200, as illustrated in, for example, FIG. 9, when a threshold voltage Vₜₕ₁ of the p-channel MOS transistor varies by ΔVₜₕ₁, the timing of a rise in a voltage Vₒᵤₜ of an output OUT is shifted by Δt₁. Further, in the CMOS transistor of the buffer circuit 200, as illustrated in, for example, FIG. 10, when a threshold voltage Vₜₕ₂ of the n-channel MOS transistor varies by ΔVₜₕ₂, the timing of a rise in the voltage Vₒᵤₜ of the output OUT is shifted by Δt₂. Therefore, there is such a problem that when, for example, the timing of a rise in the voltage Vₒᵤₜ of the output OUT varies and a mobility correction period ΔT varies by Δt₁ or Δt₂, a current I_{ds} at the time of light emission varies by ΔI_{ds} as illustrated in, for example, FIG. 11, and this variation leads to a variation in intensity. Incidentally, FIG. 11 illustrates an example of a relationship between the mobility correction period ΔT and the light emission intensity.

Incidentally, the problem of the variation in the threshold voltage Vₜₕ not only occurs in the scan circuit of the display device, but also similarly occurs in other devices.

In view of the foregoing, it is desirable to provide a drive circuit capable of reducing a variation in the timing of a rise in an output voltage, and a display device including this drive circuit.

According to an embodiment of the present invention, there is provided a drive circuit including an input-side inverter circuit and an output-side inverter circuit connected to each other in series and inserted between a high voltage line and a low voltage line. The output-side inverter circuit includes three transistors. The first one is a first transistor of a dual-gate first electro-conductive type, having a drain connected to the high voltage line side and a source connected to an output side of the output-side inverter circuit. The second one is a second transistor of a dual-gate second electro-conductive type, having a drain connected to the high voltage line side and a source connected to the output side of the output-side inverter circuit. The third one is a third transistor having a drain connected to the low voltage line side and a source connected to the output side of the output-side inverter circuit.

According to another embodiment of the present invention, there is provided a display device including a display section having a plurality of scanning lines arranged in rows, a plurality of signal lines arranged in columns and a plurality of pixels arranged in rows and columns. The display device further includes a drive section driving each of the pixels. The drive section includes a plurality of drive circuits each provided for each of the scanning lines, and each of the drive circuits in the drive section includes the same elements as those of the above-described drive circuit.

In the above-described drive circuit and display device of the embodiments, the dual-gate transistors are incorporated into the output-side inverter circuit, of the input-side inverter circuit and the output-side inverter circuit connected to each other in series. Thus, controlling one of the gate voltages and thereby changing a transistor property makes it possible to correct the threshold voltage of the transistor so that the threshold voltage becomes a certain value.

According to the above-described drive circuit and the display device of the embodiments, the gate voltage of the dual-gate transistor is controlled so that the threshold voltage of the transistor can be corrected to become a certain value. This makes it possible to reduce a variation in the timing of a rise in an output voltage of the drive circuit. Therefore, for example, in an organic EL display device, a variation in a current flowing in an organic EL element at the time of light emission can be reduced and thus, uniformity of intensity can be improved.

Other and further object, features and advantages of the present invention will appear more fully from the following description.

### BRIEF DESCRIPTION OF THE DRAWINGS

FIG. 1 is a circuit diagram illustrating an example of a buffer circuit according to an embodiment of the present invention;

FIG. 2 is a diagram illustrating a relationship between a back gate voltage and a current in a dual-gate transistor;

FIG. 3 is a waveform diagram illustrating an example of operation of the buffer circuit in FIG. 1;

FIG. 4 is a schematic structural diagram of a display device that is an example of an application example of the buffer circuit according to the embodiment;

FIG. 5 is a circuit diagram illustrating an example of a write-line driving circuit and an example of a pixel circuit in FIG. 4;

FIG. 6 is a waveform diagram illustrating an example of operation of the display device in FIG. 4;

FIG. 7 is a circuit diagram illustrating an example of a pixel circuit of a display device in related art;

FIG. 8 is a circuit diagram illustrating an example of a buffer circuit in related art;

FIG. 9 is a waveform diagram illustrating an example of operation of the buffer circuit in FIG. 8;

FIG. 10 is a waveform diagram illustrating another example of the operation of the buffer circuit in FIG. 8; and

FIG. 11 is a diagram illustrating an example of a relationship between mobility correction period and display intensity.

### DETAILED DESCRIPTION OF THE PREFERRED EMBODIMENT

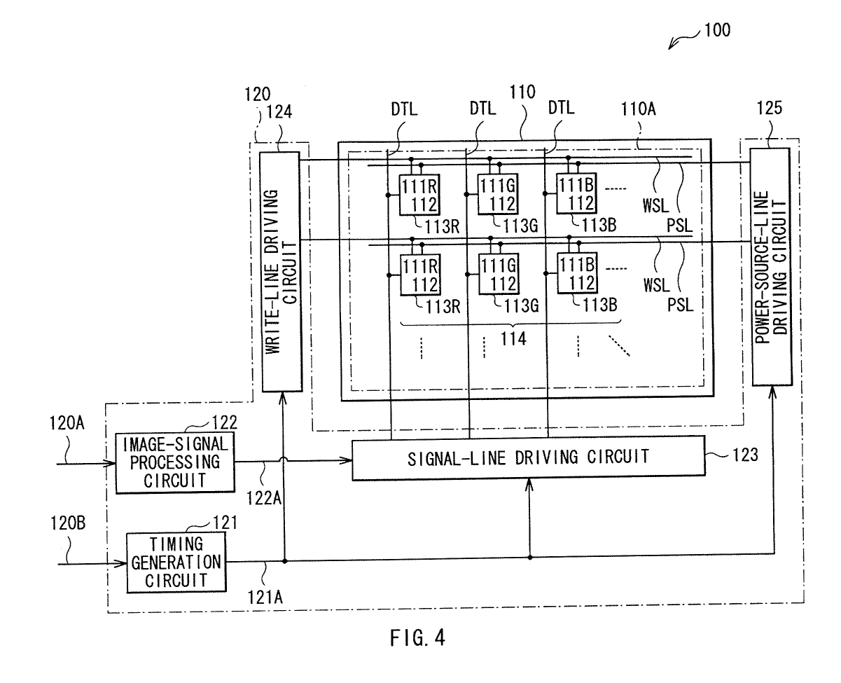

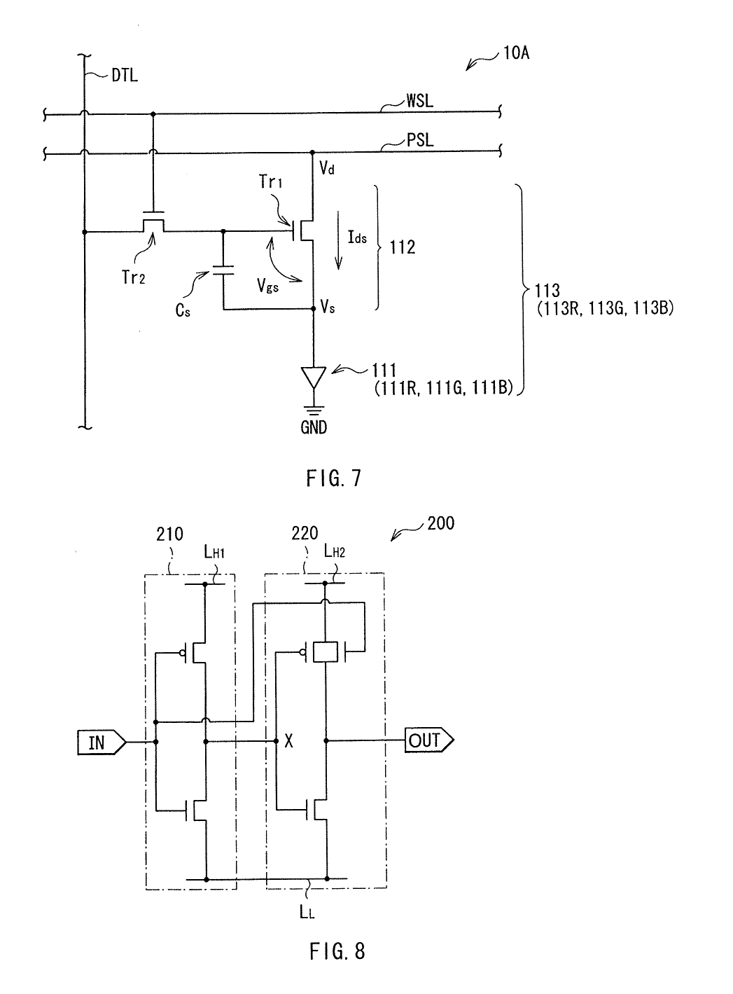

An embodiment of the present invention will be described below in detail with reference to the drawings. Incidentally, the description will be provided in the following order.
1. Embodiment (FIG. 1 through FIG. 3)
2. Application example (FIG. 4 through FIG. 6)
3. Description of related art (FIG. 7 through FIG. 11)

### Embodiment

### Structure

FIG. 1 illustrates an example of the entire structure of a buffer circuit 1 (drive circuit) according to the embodiment of the present invention. The buffer circuit 1 outputs, from an output end OUT, a pulse signal approximately in phase with a pulse signal input to an input end IN. The buffer circuit 1 includes an inverter circuit 10 (input-side inverter circuit) and an inverter circuit 20 (output-side inverter circuit).

The inverter circuits 10 and 20 output a pulse signal whose waveform is approximately the inverse of the signal waveform of the input pulse signal. The inverter circuits 10 and 20 are connected to each other in series. The inverter circuit 10 is arranged on the input end IN side in the relationship with the inverter circuit 20, and an input end of the inverter circuit 10 corresponds to the input end IN of the buffer circuit 1. On the other hand, the inverter circuit 20 is arranged on the output end OUT side in the relationship with the inverter circuit 10, and an output end of the inverter circuit 20 corresponds to the output end OUT of the buffer circuit 1. An output end (a point corresponding to A in the figure) of the inverter circuit 10 is connected to an input end of the inverter circuit 20, and the buffer circuit 1 is configured such that an output of the inverter circuit 10 is input into the inverter circuit 20.

The inverter circuit 10 is inserted between a high voltage line L_{H1} and a low voltage line L_{L}, and the inverter circuit 20 is inserted between a high voltage line L_{H2} and the low voltage line L_{L}. Here, the high voltage line L_{H1} and the high voltage line L_{H2} are independent of each other, and voltages different from each other can be applied to the high voltage line L_{H1} and the high voltage line L_{H2}.

The inverter circuit 10 includes a first electro-conductive type transistor Tr₁₁ and a second electro-conductive type transistor Tr₁₂. The transistor Tr₁₁ is, for example, a p-channel Metal Oxide Semiconductor (MOS) transistor, and the transistor Tr₁₂ is, for example, an n-channel MOS transistor.

The transistors Tr₁₁ and Tr₁₂ are connected to each other in parallel. Specifically, the respective gates of the transistors Tr₁₁ and Tr₁₂ are connected to each other. Further, a source or a drain of the transistor Tr₁₁ and a source or a drain of the transistor Tr₁₂ are connected to each other. Furthermore, the respective gates of the transistors Tr₁₁ and Tr₁₂ are connected to the input end of the inverter circuit 10 (the input end IN of the buffer circuit 1). A connection point A between the source or the drain of the transistor Tr₁₁ and the source or the drain of the transistor Tr₁₂ is connected to the output end of the inverter circuit 10. Of the source and the drain of the transistor Tr₁₁, one that is not connected to the transistor Tr₁₂ is connected to the high voltage line L_{H1}. On the other hand, of the source and the drain of the transistor Tr₁₂, one that is not connected to the transistor Tr₁₁ is connected to the low voltage line L_{L}. Incidentally, in the inverter circuit 10, an element of some kind may be provided between the transistor Tr₁₁ and the transistor Tr₁₂, between the transistor Tr₁₁ and the high voltage line L_{H1}, or between the transistor Tr₁₂ and the low voltage line L_{L}.

The inverter circuit 20 includes a first electro-conductive type transistor Tr₂₁ (first transistor), a second electro-conductive type transistor Tr₂₂ (second transistor), and a first electro-conductive type transistor Tr₂₃ (third transistor). The transistor Tr₂₁ is, for example, a p-channel MOS transistor, and each of the transistors Tr₂₂ and Tr₂₃is, for example, an n-channel MOS transistor.

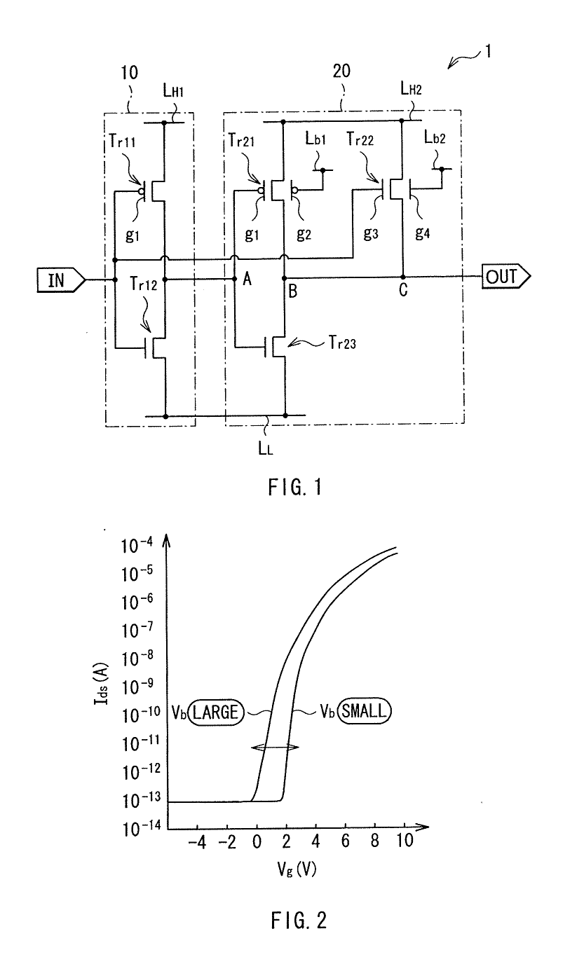

Each of the transistors Tr₂₁ and Tr₂₂ is a dual-gate transistor, and has two gate electrodes. Here, one of the two gate electrodes is an electrode to which a signal input to the input end IN of the buffer circuit 1 is to be input, and corresponds to each of gate electrodes g1 and g3 in FIG. 1. Further, the other of the two gate electrodes is an electrode to which a control signal for changing the property of the transistor is to be input, and corresponds to each of gate electrodes g2 and g4 in FIG. 1. The gate electrodes g2 and g4 are also called back gate electrodes. For example, as illustrated in FIG. 2, when a small voltage Vb is input to each of the gate electrodes g2 and g4, it may be possible to increase a threshold voltage Vₜₕ of each of the transistors Tr₂₁ and Tr₂₂. On the contrary, for example, as illustrated in FIG. 2, when a large voltage Vb is input to each of the gate electrodes g2 and g4, it may be possible to reduce the threshold voltage Vₜₕ of each of the transistors Tr₂₁ and Tr₂₂. In this way, by controlling the magnitude of a voltage applied to each of the gate electrodes g2 and g4, it may be possible to move an operating point of each of the transistors Tr₂₁ and Tr₂₂. Therefore, by adjusting the amplitude of a control signal input to each of the transistors Tr₂₁ and Tr₂₂, it may be possible to adjust the threshold voltage of each of the transistors Tr₂₁ and Tr₂₂.

The transistors Tr₂₁ and Tr₂₃ are connected to each other in parallel. Specifically, the respective gates of the transistors Tr₂₁ and Tr₂₃ are connected to each other. Further, a source or a drain of the transistor Tr₂₁ and a source or a drain of the transistor Tr₂₃ are connected to each other. Furthermore, the respective gates of the transistors Tr₂₁ and Tr₂₃ are connected to the output end of the inverter circuit 10. A connection point B between the source or the drain of the transistor Tr₂₁ and the source or the drain of the transistor Tr₂₃ is connected to the output end of the inverter circuit 20. Of the source and the drain of the transistor Tr₂₁, one that is not connected to the transistor Tr₂₃ is connected to the high voltage line L_{H2}. A connection point C between a source or a drain of the transistor Tr₂₂ and the source or the drain of the transistor Tr₂₃ is connected to, of the source and the drain of the transistor Tr₂₃, one that is not connected to the low voltage line L_{L}, and the connection point C is also connected to the output end of the inverter circuit 20. Of the source and the drain of the transistor Tr₂₂, one that is not connected to the transistor Tr₂₃ is connected to the high voltage line L_{H2}. Of the source and the drain of the transistor Tr₂₃, one that is not connected to the transistor Tr₂₁ is connected to the low voltage line L_{L}. The back gate of the transistor Tr₂₁ is connected to a control line L_{b1}. Further, the back gate of the transistor Tr₂₂ is connected to a control line L_{b2}. Incidentally, in the inverter circuit 20, an element of some kind may be provided between the transistor Tr₂₁ and the transistor Tr₂₃, between the transistor Tr₂₁ and the high voltage line L_{H2}, or between the transistor Tr₂₃ and the low voltage line L_{L}.

### Operation

Next, operation of the buffer circuit 1 in the present embodiment will be described. In the following, a threshold correction (Vₜₕ cancel) in the buffer circuit 1 will be mainly described.

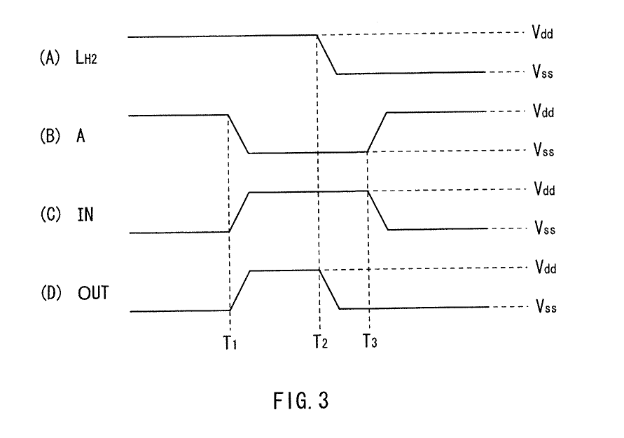

FIG. 3 illustrates an example of the operation of the buffer circuit 1. FIG. 3 illustrates an example of operation of cancelling the threshold voltage Vₜₕ included in a gate-source voltage V_{gs} of the transistor Tr₂₁.

Initially, Vₛₛ is input to the input end IN of the buffer circuit 1, and the voltage of the connection point A (the output end of the inverter circuit 10) is V_{dd}. Therefore, the transistors Tr₂₁ and Tr₂₂ are off and the transistor Tr₂₃ is on and thus, the voltage of the output end OUT of the buffer circuit 1 is Vₛₛ. Subsequently, the voltage of the input end IN rises from Vₛₛ to V_{dd} (T₁). Then, the voltage of the connection point A falls from V_{dd} to Vₛₛ. Therefore, the transistors Tr₂₁ and Tr₂₂ turn on, and the transistor Tr₂₃ turns off and thus, the voltage of the output end OUT changes from Vₛₛ to V_{dd}. Subsequently, the voltage of the high voltage line L_{H2} changes from V_{dd} to Vₛₛ (T₂). Then, the voltage of the output end OUT also changes from V_{dd} to Vₛₛ. Subsequently, the voltage of the input end IN falls from V_{dd} to Vₛₛ (T₃). Then, the voltage of the connection point A rises from Vₛₛ to V_{dd}. However, the voltage of the high voltage line L_{H2} is already Vₛₛ and thus, the transistors Tr₂₁ and Tr₂₂ remain off and the voltage of the output end OUT is maintained at Vₛₛ.

Incidentally, a rising waveform of the voltage of the output end OUT depends on the property of the transistor Tr₂₂ to which the voltage of the input end IN is input and the property of the transistor Tr₂₁ to which the voltage of the connection point A is input. Therefore, when there is a variation in the threshold voltage Vₜₕ of each of the transistors Tr₂₁ and Tr₂₂, a variation occurs in the timing of a rise in the output voltage from Vₛₛ to V_{dd}, causing the pulse width of the output voltage to deviate from a desired value. Therefore, when the buffer circuit 1 is applied to, for example, an output stage of a scanner of an organic EL display device, and a mobility correction period is defined by the pulse width of the output voltage of the buffer circuit 1, the mobility correction period varies and therefore a current flowing in the organic EL element at the time of light emission varies. As a result, there occurs such a problem that intensity becomes nonuniform.

On the other hand, in the present embodiment, it may be possible to adjust the threshold voltage of each of the transistors Tr₂₁ and Tr₂₂ to a desired value by applying the control signal to each of the gate electrodes g2 and g4. Thus, in the timing of a rise in the output voltage of the buffer circuit 1, a variation can be reduced. Therefore, even when the buffer circuit 1 is applied to, for example, the output stage of the scanner of the organic EL display device, and the mobility correction period is defined by the pulse width of the output voltage of the buffer circuit 1, the variation in the mobility correction period is small and thus, it may be possible to reduce the variation in the current flowing in the organic EL element at the time of light emission. As a result, the uniformity of intensity can be improved.

### Application Example

FIG. 4 illustrates an example of the entire structure of a display device 100 serving as an example of the application example of the buffer circuit 1 according to the above-described embodiment. This display device 100 includes, for example, a display panel 110 (display section) and a drive circuit 120 (drive section).

### Display Panel 110

The display panel 110 includes a display region 110A in which three kinds of organic EL elements 111R, 111G and 111B emitting mutually different colors are arranged two-dimensionally. The display region 110A is a region for displaying an image by using light emitted from the organic EL elements 111R, 111G and 111B. The organic EL element 111R is an organic EL element emitting red light, the organic EL element 111G is an organic EL element emitting green light, and the organic EL element 111B is an organic EL element emitting blue light. Incidentally, in the following, the organic EL elements 111R, 111G and 111B will be collectively referred to as an organic EL element 111 as appropriate.

### Display Region 110A

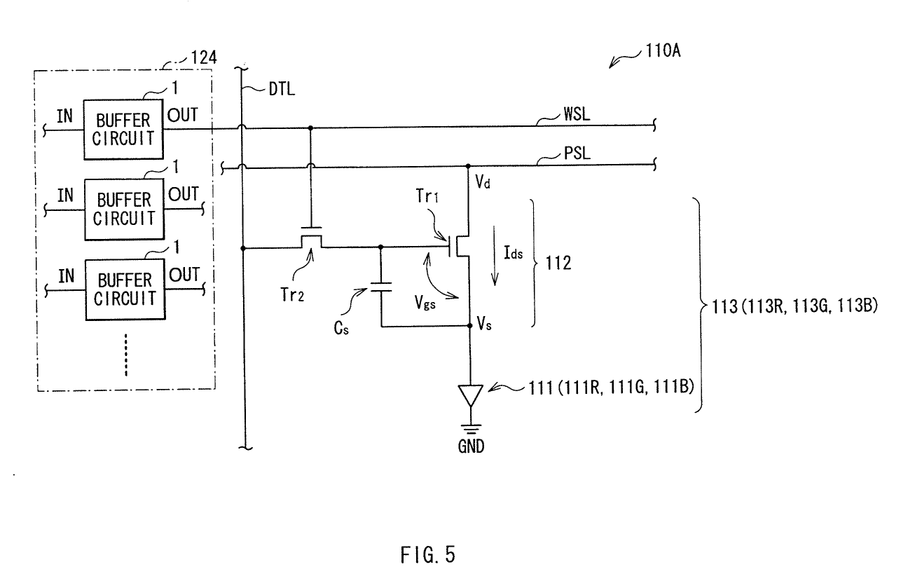

FIG. 5 illustrates an example of a circuit configuration in the display region 110A, together with an example of a write-line driving circuit 124 to be described later. In the display region 110A, plural pixel circuits 112 respectively paired with the individual organic EL elements 111 are arranged two-dimensionally. Incidentally, in the present application example, a pair of the organic EL element 111 and the pixel circuit 112 configures one pixel 113. To be more specific, as illustrated in FIG. 5, a pair of the organic EL element 111R and the pixel circuit 112 configures one pixel 113R for red, a pair of the organic EL element 111G and the pixel circuit 112 configures one pixel 113G for green, and a pair of the organic EL element 111B and the pixel circuit 112 configures one pixel 113B for blue. Further, the adjacent three pixels 113R, 113G and 113B configure one display pixel 114.

Each of the pixel circuits 112 includes, for example, a drive transistor Tr₁ controlling a current flowing in the organic EL element 111, a write transistor Tr₂ writing a voltage of a signal line DTL into the drive transistor Tr₁, and a holding capacitance Cₛ, and thus each of the pixel circuits 112 has a 2Tr1C circuit configuration. The drive transistor Tr₁ and the write transistor Tr₂ are each formed by, for example, an n-channel MOS Thin Film Transistor (TFT). The drive transistor Tr₁ or the write transistor Tr₂ may be a p-channel MOS TFT.

In the display region 110A, plural write lines WSL (scanning line) are arranged in rows and plural signal lines DTL are arranged in columns. In the display region 110A, further, plural power-source lines PSL (member to which a source voltage is supplied) are arranged in rows along the write lines WSL. Near a cross-point between each signal line DTL and each write line WSL, one organic EL element 111 is provided. Each of the signal lines DTL is connected to an output end (not illustrated) of a signal-line driving circuit 123 to be described later, and to either of a drain electrode and a source electrode (not illustrated) of the write transistor Tr₂. Each of the write lines WSL is connected to an output end (not illustrated) of the write-line driving circuit 124 to be described later and to a gate electrode (not illustrated) of the write transistor Tr₂. Each of the power-source lines PSL is connected to an output end (not illustrated) of a power-source-line driving circuit 125 to be described later, and to either of a drain electrode and a source electrode (not illustrated) of the drive transistor Tr₁. Of the drain electrode and the source electrode of the write transistor Tr₂, one (not illustrated) that is not connected to the signal line DTL is connected to a gate electrode (not illustrated) of the drive transistor Tr₁ and one end of the holding capacitance Cₛ. Of the drain electrode and the source electrode of the drive transistor Tr₁, one (not illustrated) that is not connected to the power-source line PSL and the other end of the holding capacitance Cₛ are connected to an anode electrode (not illustrated) of the organic EL element 111. A cathode electrode (not illustrated) of the organic EL element 111 is connected to, for example, a ground line GND.

### Drive Circuit 120

Next, each circuit in the drive circuit 120 will be described with reference to FIG. 4 and FIG. 5. The drive circuit 120 includes a timing generation circuit 121, an image-signal processing circuit 122, the signal-line driving circuit 123, the write-line driving circuit 124 and the power-source-line driving circuit 125.

The timing generation circuit 121 performs control so that the image-signal processing circuit 122, the signal-line driving circuit 123, the write-line driving circuit 124 and the power-source-line driving circuit 125 operate in an interlocking manner. For example, the timing generation circuit 121 is configured to output a control signal 121A to each of the above-described circuits, according to (in synchronization with) a synchronization signal 20B input externally.

The image-signal processing circuit 122 makes a predetermined correction to an image signal 120A input externally, and outputs a corrected image signal 122A to the signal-line driving circuit 123. As the predetermined correction, there are, for example, a gamma correction and an overdrive correction.

The signal-line driving circuit 123 applies, according to (in synchronization with) the input of the control signal 121A, the image signal 122A (signal voltage V_{sig}) input from the image-signal processing circuit 122, to each of the signal lines DTL, thereby performing writing into the pixel 113 to be selected. Incidentally, the writing refers to the application of a predetermined voltage to the gate of the drive transistor Tr₁.

The signal-line driving circuit 123 is configured to include, for example, a shift resistor (not illustrated), and includes a buffer circuit (not illustrated) for one stage, corresponding to each column of the pixels 113. This signal-line driving circuit 123 can output two kinds of voltages (V_{ofs}, V_{sig}) to each of the signal lines DTL, according to (in synchronization with) the input of the control signal 121A. Specifically, the signal-line driving circuit 123 supplies, via the signal line DTL connected to each of the pixels 113, the two kinds of voltages (V_{ofs}, V_{sig}) sequentially to the pixel 113 selected by the write-line driving circuit 124.

Here, the offset voltage V_{ofs} is a value lower than a threshold voltage Vₑ₁ of the organic EL element 111. Further, the signal voltage V_{sig} is a voltage value corresponding to the image signal 122A. A minimum voltage of the signal voltage V_{sig} is a voltage value lower than the offset voltage V_{ofs}, and a maximum voltage of the signal voltage V_{sig} is a voltage value higher than the offset voltage V_{ofs}.

The write-line driving circuit 124 is configured to include, for example, a shift resistor (not illustrated), and includes the buffer circuit 1 for each stage, corresponding to each row of the pixels 113. This write-line driving circuit 124 can output two kinds of voltages (V_{dd}, Vₛₛ) to each of the write lines WSL, according to (in synchronization with) the input of the control signal 121A. Specifically, the write-line driving circuit 124 supplies, via the write line WSL connected to each of the pixels 113, the two kinds of voltages (V_{dd}, Vₛₛ) to the pixel 113 to be driven, thereby controlling the write transistor Tr₂.

Here, the voltage V_{dd} is a value equal to or higher than an ON voltage of the write transistor Tr₂. V_{dd} is the value of a voltage output from the write-line driving circuit 124 at the time of extinction or at the time of a threshold correction to be described later. Vₛₛ is a value lower than the ON voltage of the write transistor Tr₂, and also lower than V_{dd}.

The power-source-line driving circuit 125 is configured to include, for example, a shift resistor (not illustrated), and includes, for example, a buffer circuit (not illustrated) for each stage, corresponding to each row of the pixels 113. This power-source-line driving circuit 125 can output two kinds of voltages (V_{ccH}, V_{ccL}) according to (in synchronization with) the input of the control signal 121A. Specifically, the power-source-line driving circuit 125 supplies, via the power-source line PSL connected to each of the pixels 113, the two kinds of voltages (V_{ccH}, V_{ccL}) to the pixel 113 to be driven, thereby controlling the light emission and extinction of the organic EL element 111.

Here, the voltage V_{ccL} is a value lower than a voltage (Vₑ₁+V_{ca}) that is the sum of the threshold voltage Vₑ₁ of the organic EL element 111 and a voltage V_{ca} of the cathode of the organic EL element 111. Further, the voltage V_{ccH} is a value equal to or higher than the voltage (Vₑ₁+V_{ca}).

Next, an example of the operation (operation from extinction to light emission) of the display device 100 according to the present application example will be described. In the present application example, in order that even when the threshold voltage Vₜₕ and the mobility μ of the drive transistor Tr₁ change over time, light emission intensity of the organic EL element 111 may remain constant without being affected by these changes, correction operation for the change of the threshold voltage Vₜₕ and the mobility μ is incorporated.

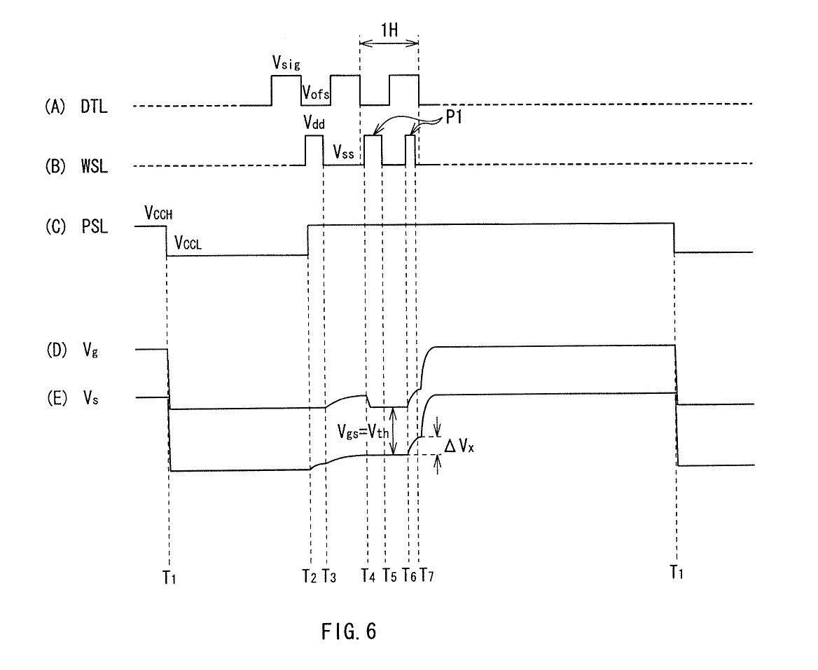

FIG. 6 illustrates an example of the waveform of a voltage applied to the pixel circuit 112 and an example of a change in each of a gate voltage V_{g} and a source voltage Vₛ of the drive transistor Tr₁. In Part (A) of FIG. 6, there is illustrated a state in which the signal voltage V_{sig} and the offset voltage V_{ofs} are applied to the signal line DTL. In Part (B) of FIG. 6, there is illustrated a state in which the voltage V_{dd} for turning on the drive transistor Tr₁ and the voltage Vₛₛ for turning off the drive transistor Tr₁ are applied to the write line WSL. In Part (C) of FIG. 6, there is illustrated a state in which the high voltage V_{ccH} and the low voltage V_{ccL} are applied to the power-source line PSL. Further, in Part (D) and Part (E) of FIG. 6, there is illustrated a state in which the gate voltage V_{g} and the source voltage Vₛ of the drive transistor Tr₁ change over time in response to the application of the voltages to the power-source line PSL, the signal line DTL and the write line WSL.

### Vₜₕ Correction Preparation Period

First, a preparation for the Vₜₕ correction is made. Specifically, when the voltage of the write line WSL is V_{off}, the voltage of the signal line DTL is V_{sig}, and the voltage of the power-source line PSL is V_{ccH} (in other words, when the organic EL element 111 is emitting light), the power-source-line driving circuit 125 reduces the voltage of the power-source line PSL from V_{ccH} to V_{ccL} (T₁). Then, the source voltage Vₛ becomes V_{ccL}, and the organic EL element 111 stops emitting the light. Next, the signal-line driving circuit 123 switches the voltage of the signal line DTL from V_{sig} to V_{ofs} and subsequently, while the voltage of the power-source line PSL is V_{ccH}, the write-line driving circuit 124 increases the voltage of the write line WSL from V_{off} to Vₒₙ. Then, the gate voltage V_{g} drops to V_{ofs}. At the time, in the power-source-line driving circuit 125 and the signal-line driving circuit 123, the voltages (V_{ccL}, V_{ofs}) applied to the power-source line PSL and the signal line DTL are set so that the gate-source voltage V_{gs} (=V_{ofs}−V_{ccL}) is larger than the threshold voltage Vₜₕ of the drive transistor Tr₁.

### First Vₜₕ Correction Period

Next, the correction of Vₜₕ is performed. Specifically, while the voltage of the signal line DTL is V_{ofs}, the power-source-line driving circuit 125 increases the voltage of the power-source line PSL from V_{ccL} to V_{ccH} (T₂). Then, a current I_{ds} flows between the drain and the source of the drive transistor Tr₁, and the source voltage Vₛ rises. Subsequently, before the signal-line driving circuit 123 switches the voltage of the signal line DTL from V_{ofs} to V_{sig}, the write-line driving circuit 124 reduces the voltage of the write line WSL from Vₒₙ to V_{off} (T₃). Then, the gate of the drive transistor Tr₁ enters a floating state, and the correction of Vₜₕ stops.

### First Vₜₕ Correction Stop Period

In a period during which the Vₜₕ correction is stopped, in, for example, other row (pixels) different from the row (pixels) to which the previous Vₜₕ correction is made, the voltage of the signal line DTL is sampled. Incidentally, at the time, in the row (pixels) to which the previous Vₜₕ correction is made, the source voltage Vₛ is lower than V_{ofs}−Vₜₕ.

Therefore, during the Vₜₕ correction stop period as well, in the row (pixels) to which the previous Vₜₕ correction is made, the current I_{ds} flows between the drain and the source of the drive transistor Tr₁, the source voltage Vₛ rises, and the gate voltage V_{g} also rises due to coupling via the holding capacitance Cₛ.

### Second Vₜₕ Correction Period

Next, the Vₜₕ correction is made again. Specifically, when the voltage of the signal line DTL is V_{ofs} and the Vₜₕ correction is possible, the write-line driving circuit 124 increases the voltage of the write line WSL from V_{off} to Vₒₙ, thereby causing the gate of the drive transistor Tr₁ to be V_{ofs} (T₄). At the time, when the source voltage Vₛ is lower than V_{ofs}−Vₜₕ (when the Vₜₕ correction is not completed yet), the current I_{ds} flows between the drain and the source of the drive transistor Tr₁, until the drive transistor Tr₁ is cut off (until the gate-source voltage V_{gs} becomes Vₜₕ). Subsequently, before the signal-line driving circuit 123 switches the voltage of the signal line DTL from V_{ofs} to V_{sig}, the write-line driving circuit 124 reduces the voltage of the write line WSL from Vₒₙ to V_{off} (T₅). Then, the gate of the drive transistor Tr₁ enters a floating state and thus, it may be possible to keep the gate-source voltage V_{gs} constant, regardless of the magnitude of the voltage of the signal line DTL.

Incidentally, during this Vₜₕ correction period, when the holding capacitance Cₛ is charged to be Vₜₕ, and the gate-source voltage V_{gs} becomes Vₜₕ, the drive circuit 120 completes the Vₜₕ correction. However, when the gate-source voltage V_{gs} does not reach Vₜₕ, the drive circuit 120 repeats the Vₜₕ correction and the Vₜₕ correction stop, until the gate-source voltage V_{gs} reaches Vₜₕ.

### Writing And μ Correction Period

After the Vₜₕ correction stop period ends, the writing and the μ correction are performed. Specifically, while the voltage of the signal line DTL is V_{sig}, the write-line driving circuit 124 increases the voltage of the write line WSL from V_{off} to Vₒₙ (T₆), and connects the gate of the drive transistor Tr₁ to the signal line DTL. Then, the voltage V_{g} of the drive transistor Tr₁ becomes the voltage V_{sig} of the signal line DTL. At the time, an anode voltage of the organic EL element 111 is still smaller than the threshold voltage Vₑ₁ of the organic EL element 111 at this stage, and the organic EL element 111 is cut off. Therefore, the current I_{ds} flows in an element capacitance (not illustrated) of the organic EL element 111 and therefore the element capacitance is charged and thus, the source voltage Vₛ rises by ΔVₓ, and the gate-source voltage V_{gs} soon becomes V_{sig}+Vₜₕ−Vₓ. In this way, the μ correction is performed concurrently with the writing. Here, the larger the mobility μ of the drive transistor Tr₁ is, the larger ΔVₓ is. Therefore, by reducing the gate-source voltage V_{gs} by ΔVₓ, a variation in the mobility μ for each pixel 113 can be removed.

### Light Emission Period

Lastly, the write-line driving circuit 124 reduces the voltage of the write line WSL from Vₒₙ to V_{off} (T₈). Then, the gate of the drive transistor Tr₁ enters a floating state, the current I_{ds} flows between the drain and the source of the drive transistor Tr₁, and the source voltage Vₛ rises. As a result, a voltage equal to or higher than the threshold voltage Vₑ₁ is applied to the organic EL element 111, and the organic EL element 111 emits light of desired intensity.

In the display device 100 of the present application example, as described above, the pixel circuit 112 is subjected to on-off control in each pixel 113, and the driving current is fed into the organic EL element 111 of each pixel 113, so that holes and electrons recombine and therefore emission of light occurs, and this light is extracted to the outside. As a result, an image is displayed in the display region 110A of the display panel 110.

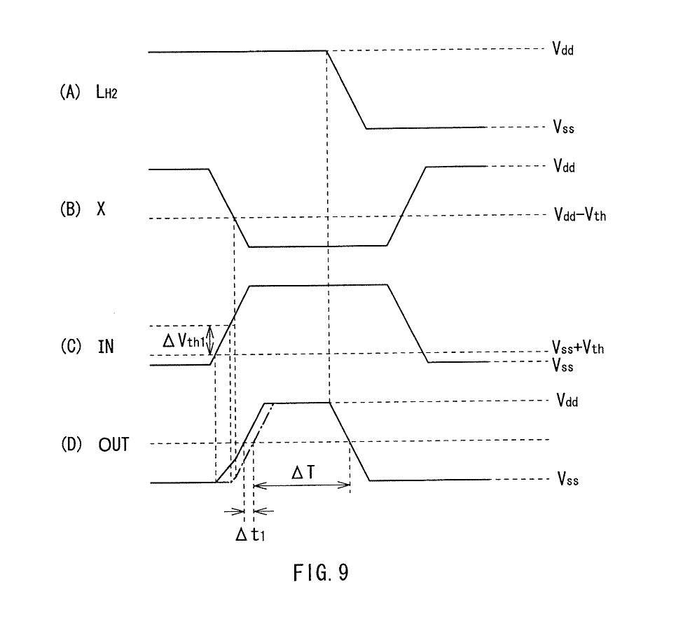

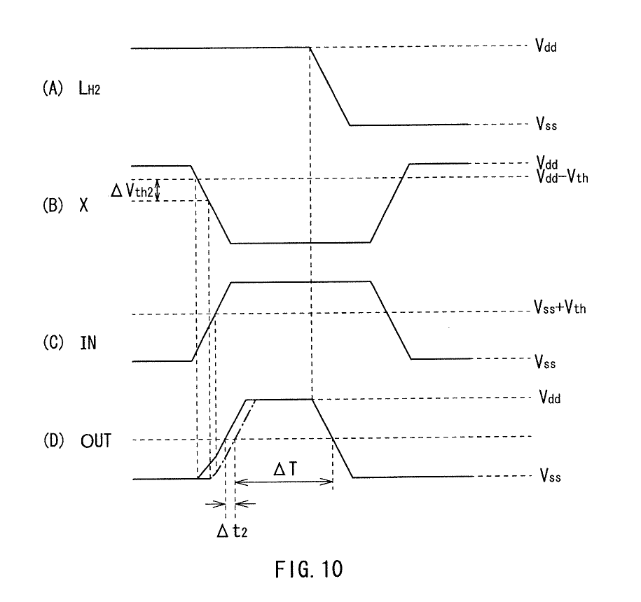

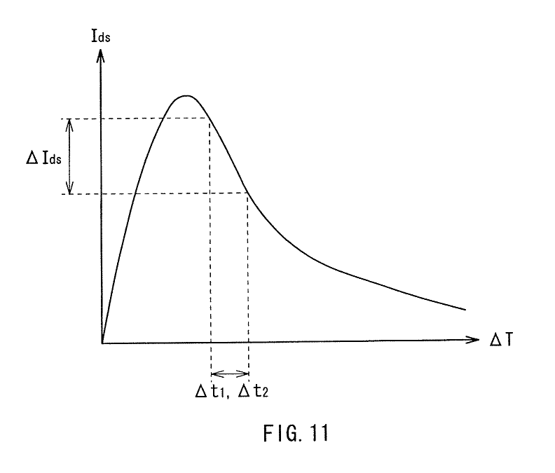

Incidentally, in related art, in the display device of the active matrix system, typically, as illustrated in FIG. 8, the buffer circuit in the scan circuit is configured by connecting the two inverter circuits 210 and 220 in series. However, in the buffer circuit 200, for example, as illustrated in FIG. 9, when the threshold voltage Vₜₕ₁ of the p-channel MOS transistor varies by ΔVₜₕ₁, the timing of a rise in the voltage Vₒᵤₜ of the output OUT is shifted by Δt₁. Further, in the buffer circuit 200, for example, as illustrated in FIG. 10, when the threshold voltage Vₜₕ₂ of the n-channel MOS transistor varies by ΔVₜₕ₂, the timing of a drop in the voltage Vₒᵤₜ of the output OUT is shifted by Δt₂. Therefore, for example, there is such a problem that when the timing of a rise and the timing of a drop in the voltage Vₒᵤₜ of the output OUT vary and the mobility correction period ΔT varies by Δt₁+Δt₂, the current I_{ds} at the time of light emission varies by ΔI_{ds} as illustrated in, for example, FIG. 11, and this variation leads to a variation in intensity.

On the other hand, in the present application example, the buffer circuit 1 according to the above-described embodiment is used in an output stage of the write-line driving circuit 124. Thus, the mobility correction period can be defined with the pulse width of the output voltage of the buffer circuit 1. This makes it possible to reduce a variation in the mobility correction period and therefore, a variation in the current I_{ds} flowing in the organic EL element 111 at the time of light emission can be reduced and uniformity of intensity can be improved.

Up to this point, the present invention has been described by using the embodiment and the application example, but the present invention is not limited to the embodiment and like and may be variously modified.

For example, in the application example, the buffer circuit 1 according to the above-described embodiment is used in the output stage of the write-line driving circuit 124. However, this buffer circuit 1 may be used in an output stage of the power-source-line driving circuit 125 instead of the output stage of the write-line driving circuit 124, or may be used in the output stage of the power-source-line driving circuit 125 together with the output stage of the write-line driving circuit 124.

Further, in the above-described embodiment and the like, the gate voltage of the transistor Tr₂₂ before the Vₜₕ correction operation is acceptable as long as it is lower than V_{dd}+Vₜₕ₁, and the gate voltage of the transistor Tr₂₁ before the Vₜₕ correction operation is acceptable as long as it is higher than Vₛₛ+Vₜₕ₂. Therefore, when setting the gate voltage of the transistor Tr₂₂ before the Vₜₕ correction operation, a voltage line other than the high voltage lines L_{H1} and L_{H2} may be used. Also, when setting the gate voltage of the transistor Tr₂₁ before the Vₜₕ correction operation, a voltage line other than the low voltage line L_{L} may be used.

The present application contains subject matter related to that disclosed in Japanese Priority Patent Application JP 2009-295551 filed in the Japan Patent Office on Dec. 25, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A drive circuit comprising:
an input-side inverter circuit and an output-side inverter circuit connected to each other in series and inserted between a high voltage line and a low voltage line,
wherein the output-side inverter circuit includes
a first transistor of a dual-gate first electro-conductive type, having a drain connected to the high voltage line side and a source connected to an output side of the output-side inverter circuit,
a second transistor of a dual-gate second electro-conductive type, having a drain connected to the high voltage line side and a source connected to the output side of the output-side inverter circuit, and
a third transistor having a drain connected to the low voltage line side and a source connected to the output side of the output-side inverter circuit.

2. A display device comprising:
a display section including a plurality of scanning lines arranged in rows, a plurality of signal lines arranged in columns and a plurality of pixels arranged in rows and columns; and
a drive section driving each of the pixels,
wherein the drive section includes a plurality of drive circuits each provided for each of the scanning lines,
each of the drive circuits includes an input-side inverter circuit and an output-side inverter circuit connected to each other in series and inserted between a high voltage line and a low voltage line, and
the output-side inverter circuit includes
a first transistor of a dual-gate first electro-conductive type, having a drain connected to the high voltage line side and a source connected to an output side of the output-side inverter circuit, and
a second transistor of a dual-gate second electro-conductive type, having a drain connected to the high voltage line side and a source connected to the output side of the output-side inverter circuit, and
a third transistor having a drain connected to the low voltage line side and a source connected to the output side of the output-side inverter circuit.
